(19) United States
(12) Patent Application Publication
(10) Pub. No.: US 2024/0178041 A1
(43) Pub. Date: May 30, 2024

(54) RESIN MEMBER AND DIVIDING APPARATUS

(71) Applicant: DISCO CORPORATION, Tokyo (JP)

(72) Inventor: Ayumu SAKAI, Tokyo (JP)

(21) Appl. No.: 18/513,908

(22) Filed: Nov. 20, 2023

(30) Foreign Application Priority Data
Nov. 30, 2022 (JP) 2022-191011

(51) Int. Cl. H01L 21/683; H01L 21/67

(52) U.S. Cl. CPC H01L 21/6836; H01L 21/67092; H01L 21/67253

(57) ABSTRACT

A resin member for supporting a workpiece has urethane linkages deriving from a reaction between a polyether polyol and an aliphatic isocyanate. Note that, preferably, the resin member has transmittance of not less than 74.88 for light of a wavelength of 550 nm. In addition, preferably, the resin member has Shore A hardness of 50 to 90.

### BACKGROUND OF THE INVENTION

### Field of the Invention

The present invention relates to a resin member for supporting a workpiece and a dividing apparatus for dividing the workpiece.

### Description of the Related Art

In the device chip manufacturing process, a wafer formed with devices in a plurality of regions partitioned by a plurality of intersecting streets (scheduled division lines) is used. By dividing this wafer along the streets, a plurality of device chips each including the device are obtained. The device chips are incorporated into various electronic apparatuses such as mobile phones and personal computers.

For dividing the wafer, a cutting apparatus for cutting the wafer by an annular cutting blade is used. In addition, in recent years, development of a process for dividing the wafer by laser processing is also underway. For example, a laser beam capable of being transmitted through the wafer is scanned along the streets, with a focal point of the laser beam being set inside the wafer, whereby modified layers are formed inside the wafer along the streets. Those regions of the wafer in which the modified layers are formed become more brittle than the other regions. Hence, when an external force is exerted on the wafer formed with the modified layers, the modified layers function as division start points, and the wafer is divided along the streets (see Japanese Patent Laid-open No. 2004-179302). For example, the wafer is supported by a predetermined support member, and a pressing member such as a blade or a roller is pressed against the wafer, whereby an external force is exerted on the wafer (see Japanese Patent Laid-open No. 2010-135484, Japanese Patent Laid-open No. 2016-154173).

### SUMMARY OF THE INVENTION

At the time of dividing a workpiece formed with the division start points, checking of whether or not the workpiece has been suitably divided may be carried out, together with the exertion of an external force on the workpiece. Specifically, in a state in which the workpiece is supported by a transparent support member, while the pressing member is pressed against the upper surface side of the workpiece, the lower surface side of the workpiece is imaged and observed through the support member. As a result, it can be monitored whether or not the workpiece has been suitably divided by the exertion of the external force thereon.

Note that, when the pressing member is pressed against the workpiece, the workpiece is pressed against the support member. In this instance, if the support member is a hard member, deformation of the workpiece may be hampered, and division thereof may be less likely to occur, or an excessive pressure may be exerted on the workpiece to damage the workpiece. In view of this, a resin member formed of flexible resin is often used as the support member for supporting the workpiece. When the workpiece is supported by the resin member, the resin member is deformed when the pressing member is pressed against the workpiece, and, hence, deformation and division of the workpiece are accelerated, and the pressure to be exerted on the workpiece is mitigated.

However, the resin member is liable to be gradually discolored with the lapse of time. When the resin member is discolored, the transparency of the resin member is lowered, and transmittance of the resin member for visible light is lowered. As a result, the image obtained by imaging the workpiece through the resin member becomes unclear, making it difficult to check whether or not the workpiece has been suitably divided.

The present invention has been made in consideration of such a problem, and, accordingly, it is an object of the present invention to provide a resin member that is less likely to be discolored and that is used for supporting a workpiece, and to provide a dividing apparatus for dividing the workpiece supported by the resin member.

In accordance with an aspect of the present invention, there is provided a resin member for supporting a workpiece, in which the resin member has urethane linkages deriving from a reaction between a polyether polyol and an aliphatic isocyanate.

Note that, preferably, the resin member has transmittance of not less than 74.8% for light of a wavelength of 550 nm. In addition, preferably, the resin member has Shore A hardness of 50 to 90. Further, preferably, the aliphatic isocyanate is hexamethylene diisocyanate.

In accordance with another aspect of the present invention, there is provided a dividing apparatus that divides a workpiece formed with division start points along streets, along the streets, the dividing apparatus including a resin member that supports the workpiece, a pressing member that presses the workpiece supported by the resin member, and an imaging unit that images the workpiece through the resin member, in which the resin member has urethane linkages deriving from a reaction between a polyether polyol and an aliphatic isocyanate.

Note that, preferably, the resin member has transmittance of not less than 74.8% for light of a wavelength of 550 nm. In addition, preferably, the resin member has Shore A hardness of 50 to 90. Further, preferably, the aliphatic isocyanate is hexamethylene diisocyanate.

The resin member according to one mode of the present invention has urethane linkages deriving from a reaction between a polyether polyol and an aliphatic isocyanate. As a result, it is possible to exert an external force on a workpiece in a state in which the workpiece is supported by the resin member which is less likely to be discolored.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view depicting a resin member that supports a workpiece;

FIG. 2 is a cross-sectional view depicting a dividing apparatus; and

FIG. 3 is a graph depicting the transmittance of each of resin members.

### DETAILED DESCRIPTION OF THE PREFERRED EMBODIMENT

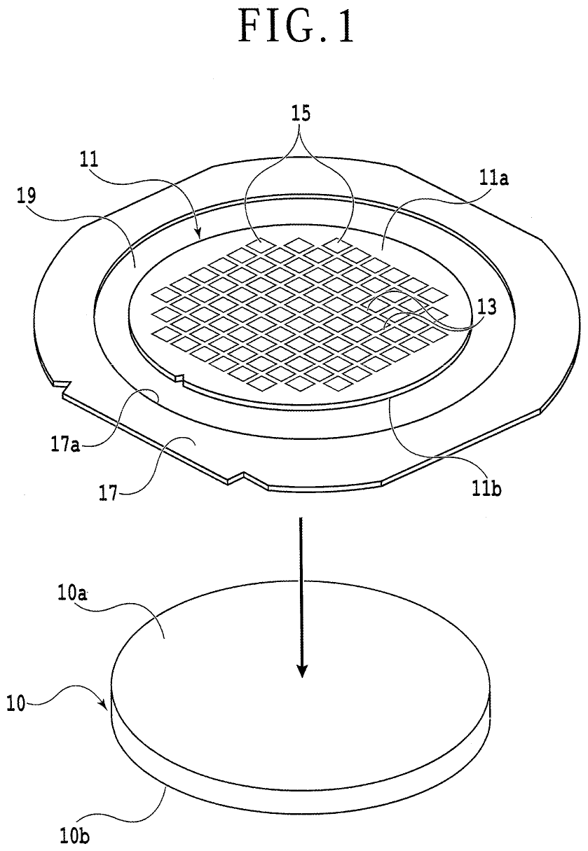

An embodiment according to one mode of the present invention will be described below with reference to the attached drawings. First, a configuration example of a resin member according to the present embodiment will be described. FIG. 1 is a perspective view depicting a resin member 10 for supporting a workpiece 11.

For example, the workpiece 11 is a disk-shaped wafer formed of a semiconductor material such as single crystal silicon, and has a front surface (first surface) 11a and a back surface (second surface) 11b which are substantially parallel to each other. The workpiece 11 is partitioned into a plurality of rectangular regions by a plurality of streets (scheduled division lines) 13 arranged in a grid pattern in such a manner as to intersect each other. In addition, devices 15 such as an integrated circuit (IC), large scale integration (LSI), and micro electro mechanical systems (MEMS) are formed on the front surface 11a side of the plurality of regions partitioned by the streets 13. Note that the material, shape, structure, size, and the like of the workpiece 11 are not limited to any particular kind. For example, the workpiece 11 may be a wafer (substrate) formed of any of other semiconductors than silicon (GaAs, SiC, InP, GaN, etc.), sapphire, glass, ceramic, resin, metal, or the like. Besides, the kind, number, shape, structure, size, layout, and the like of the devices 15 are also not limited to any particular kind, and the workpiece 11 may not be formed with the devices 15.

At the time of dividing the workpiece 11, for the convenience of handling (transportation, holding, or the like) of the workpiece 11, the workpiece 11 is supported by an annular frame 17. The frame 17 is a disk-shaped member formed of metal such as stainless steel (SUS), and the frame 17 is provided in its central part with a circular opening 17a penetrating the frame 17 in the thickness direction. Note that the diameter of the opening 17a is larger than the diameter of the workpiece 11.

A circular sheet 19 is fixed to the workpiece 11 and the frame 17. For example, as the sheet 19, there is used a tape that includes a film form base material formed in a circular shape and a pressure sensitive adhesive layer (glue layer) provided on the base material. The base material is formed of resin such as polyolefin, polyvinyl chloride, or polyethylene terephthalate. The pressure sensitive adhesive layer is formed of an epoxy-based, acrylic-based, or rubber-based adhesive or the like. Note that the pressure sensitive adhesive layer may be ultraviolet (UV)-curing resin that cures when irradiated with ultraviolet rays. Further, the sheet 19 may be a thermocompression adhesive sheet that can undergo thermocompression adhesion to the workpiece 11 and the frame 17 and that has no pressure sensitive adhesive layer (glue layer). In a state in which the workpiece 11 is disposed inside the opening 17a of the frame 17, a central part of the sheet 19 is stuck to the back surface 11b side of the workpiece 11, and a peripheral part of the sheet 19 is stuck to the frame 17. As a result, the workpiece 11 is supported by the frame 17 through the sheet 19.

The workpiece 11 is formed with division start points (trigger for division) along the streets 13. For example, a laser beam is applied to the workpiece 11 under such conditions that the workpiece 11 is modified (altered) through multiphoton absorption. Specifically, a laser beam which can be transmitted through the workpiece 11 is scanned along the streets 13, with a focal point of the laser beam being positioned inside the workpiece 11. As a result, modified layers (altered layers) are formed inside the workpiece 11 along the streets 13. Those regions of the workpiece 11 in which the modified layers are formed become more brittle than the other regions. Hence, when an external force is exerted on the workpiece 11 formed with the modified layers, the workpiece 11 is broken with the modified layers as division start points, and is divided along the streets 13. As a result, a plurality of chips (device chips) each provided with the device 15 are formed.

It is to be noted, however, that the division start points formed in the workpiece 11 are not limited to the modified layers. For example, grooves (cut grooves) may be formed on the front surface 11a side or the back surface 11b side of the workpiece 11 along the streets 13, by cutting the workpiece 11 by an annular cutting blade. Alternatively, grooves (laser processed grooves) may be formed on the front surface 11a side or the back surface 11b side of the workpiece 11 along the streets 13, by applying a laser beam capable of being absorbed by the workpiece 11 to the workpiece 11 and performing ablation processing. In this case, the grooves formed along the streets 13 function as the division start points of the workpiece 11.

At the time of exerting the external force on the workpiece 11, the workpiece 11 is supported by the resin member 10. For example, the resin member 10 is formed in a disk shape, and has a first surface 10a and a second surface 10b which are substantially parallel to each other. The first surface 10a of the resin member 10 constitutes a flat support surface for supporting the workpiece 11. The diameter of the resin member 10 is larger than the diameter of the workpiece 11. Hence, by placing the workpiece 11 on the resin member 10, the whole part of the workpiece 11 can be supported by the first surface 10a of the resin member 10. Note that the shape and size of the resin member 10 are not limited insofar as the whole part of the workpiece 11 can be supported.

The resin member 10 is a flexible member made of polyurethane which is formed by a polyaddition reaction of a polyol and an isocyanate. Particularly, in the present embodiment, the resin member 10 is formed with use of a polyurethane which is formed by a reaction between a polyether polyol and an aliphatic isocyanate. Hence, the resin member 10 has urethane linkages deriving from the reaction between the polyether polyol and the aliphatic isocyanate. Note that the aliphatic isocyanate may be either a polymer or a prepolymer. For example, the resin member 10 is a polyurethane produced by a polyaddition reaction between a polyether polyol having a molecular weight of not less than 3,000 and hexamethylene diisocyanate (HDI). Note that the isocyanate used for synthesis of the polyurethane may be a mixture of polyisocyanates formed by addition of a polyvalent alcohol to hexamethylene diisocyanate or the like. In addition, in the case where the polyether polyol and the aliphatic isocyanate are put into reaction with each other, a crosslinking agent such as dipropylene glycol (DPG) and a catalyst such as triethylenediamine or stannous octoate may be added.

Here, a polyurethane synthesized by use of an aromatic isocyanate such as diphenylmethane diisocyanate (MDI) and tolylene diisocyanate (TDI) is liable to be changed in color to yellow (yellowing) due to quinoidization of a benzene ring by irradiation with light or the like. On the other hand, a polyurethane synthesized by use of the aliphatic isocyanate is not liable to undergo the above-mentioned discoloration. Hence, by use of a polyurethane produced by a reaction between the polyether polyol and the aliphatic isocyanate, a resin member 10 that is not liable to undergo discoloration when irradiated with light and that can maintain, for a long time, a state in which transmittance for visible light is high is obtained. For example, in the case where the thickness of the resin member 10 is 15 mm, a state in which the transmittance of the resin member 10 is not less than 74.8% for light (visible light) of a wavelength of 550 nm can be maintained for one year.

In addition, in the case where the workpiece 11 is supported by the resin member 10, the Shore A hardness of the resin member 10 is preferably 50 to 90, more preferably 60 to 80. Accordingly, when an external force is exerted on the workpiece 11 while the workpiece 11 is suitably supported by the resin member 10, the workpiece 11 can be suitably deformed, and the pressure to be exerted on the workpiece 11 can thereby be mitigated. The hardness of the resin member 10 can be adjusted by the ratio of the blending amounts of the polyether polyol, the aliphatic isocyanate, and the crosslinking agent. For example, when the blending amount of the polyether polyol (polypropylene glycol) is adjusted in the range of 19.15 to 61.45 wt %, the blending amount of the aliphatic isocyanate (HDI) is adjusted in the range of 32.69 to 61.45 wt %, and the blending amount of the crosslinking agent (dipropylene glycol) is adjusted in the range of 6.69 to 19.15 wt %, a resin member 10 having the Shore A hardness of 50 to 90 can be obtained.

The workpiece 11 is placed on the first surface 10a of the resin member 10 through the sheet 19, and is supported by the resin member 10. In this state, an external force is exerted on the workpiece 11, whereby the workpiece 11 is divided along the streets 13 with the division start points as a trigger for division.

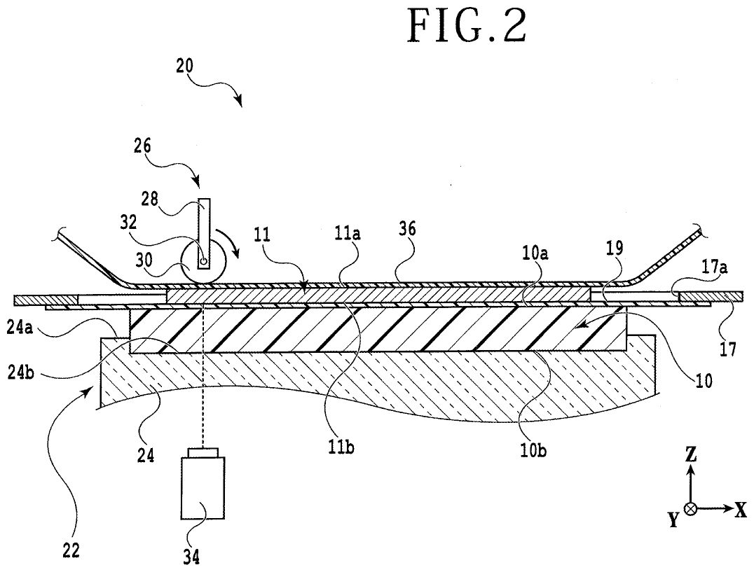

Next, a configuration example of a dividing apparatus for exerting an external force on the workpiece 11 to divide the workpiece 11 will be described. FIG. 2 is a perspective view depicting a dividing apparatus 20. Note that, in FIG. 2, an X-axis direction (first horizontal direction) and a Y-axis direction (second horizontal direction) are directions perpendicular to each other. In addition, a Z-axis direction (height direction, vertical direction, up-down direction) is a direction perpendicular to the X-axis direction and the Y-axis direction.

The dividing apparatus 20 includes a holding table 22 for holding the workpiece 11. The holding table 22 includes a cylindrical frame body (main body section) 24 including a transparent body formed of glass (quartz glass, borosilicate glass, soda-lime glass, non-alkali glass, or the like), resin, or the like and the above-described resin member 10. The frame body 24 is provided in a central part on an upper surface 24a side thereof with a cylindrical recess (groove) 24b. The diameter of the recess 24b is set to be substantially equal to the diameter of the resin member 10, and the depth of the recess 24b is set to be not more than the thickness of the resin member 10. The resin member 10 is fixed by being fitted into the recess 24b of the frame body 24 in such a manner that the first surface 10a is exposed on the upper side. As a result, the first surface 10a of the resin member 10 is disposed in such a manner as to be on the same plane as the upper surface 24a of the frame body 24 or to project upward from the upper surface 24a of the frame body 24.

On the upper side of the holding table 22, an external force exerting unit 26 for exerting an external force on the workpiece 11 is provided. For example, the external force exerting unit 26 includes a support member 28 and a pressing member 30 for pressing the workpiece 11. The pressing member 30 is a cylindrical roller having a length not less than the diameter of the workpiece 11, and is mounted to the support member 28 through a support shaft 32. The support shaft 32 is connected to the support member 28 in such a manner as to extend along the Y-axis direction. In addition, the pressing member 30 is provided in a central part thereof with a through-hole (not illustrated) penetrating the pressing member 30 in the lengthwise direction thereof, and the support shaft 32 is inserted into the through-hole in the pressing member 30. As a result, the pressing member 30 is supported in a state of being freely rotatable around the support shaft 32.

It is to be noted, however, that the configuration of the external force exerting unit 26 is not limited to any kind insofar as an external force can be exerted on the workpiece 11. For example, the external force exerting unit 26 may include a plate-shaped, columnar, or disk-shaped pressing member for pressing the workpiece 11, in place of the pressing member 30.

On the lower side of the holding table 22, an imaging unit 34 for imaging the workpiece 11 is provided. The imaging unit 34 includes an image sensor such as a charge-coupled device (CCD) sensor or a complementary metal-oxide semiconductor (CMOS) sensor, and images the workpiece 11 supported by the resin member 10. For example, a visible light camera is used as the imaging unit 34. In this case, the frame body 24 includes a member having transmittance for visible light.

At the time of dividing the workpiece 11 by the dividing apparatus 20, first, the workpiece 11 formed with the division start points (the modified layers, the cut grooves, the laser processed grooves, or the like) along the streets 13 (see FIG. 1) is held by the holding table 22. Specifically, the workpiece 11 is disposed on the holding table 22 in such a manner that the front surface 11a side thereof is directed upward and the back surface 11b side (the sheet 19 side) thereof faces the first surface 10a of the resin member 10. As a result, the back surface 11b side of the workpiece 11 is supported by the resin member 10 through the sheet 19. Note that, in the periphery of the holding table 22, clamps (not illustrated) for gripping and fixing the frame 17 may be provided. For example, a plurality of clamps are arranged at substantially equal intervals along the circumferential direction of the frame body 24. In this case, when the workpiece 11 is disposed on the holding table 22, the frame 17 is gripped by the plurality of clamps.

Next, a protective member 36 is disposed on the front surface 11a side of the workpiece 11. For example, as the protective member 36, a sheet formed of resin such as polyolefin, polyvinyl chloride, or polyethylene terephthalate is laid in such a manner as to cover the whole part on the front surface 11a side of the workpiece 11. As a result, the devices 15 (see FIG. 1) formed on the front surface 11a side of the workpiece 11 and the like are protected.

Subsequently, the front surface 11a side of the workpiece 11 is pressed by the pressing member 30 through the protective member 36. Specifically, the pressing member 30 is rolled on the workpiece 11 while being pressed against the protective member 36. As a result, the pressing member 30 presses the workpiece 11 sequentially from one end (the left end in FIG. 2) to the other end (the right end in FIG. 2) of the workpiece 11, and an external force is exerted on the whole part of the workpiece 11. When the external force is exerted on the workpiece 11, the workpiece 11 is broken with the division start points as a trigger of division. As a result, the workpiece 11 is divided along the streets 13, whereby a plurality of chips (device chips) including the devices 15 (see FIG. 1) are manufactured.

In addition, when the pressing member 30 presses the workpiece 11, the imaging unit 34 images the side of that surface of the workpiece 11 which is supported by the resin member 10 (the back surface 11b side), through the frame body 24 of the holding table 22 and the resin member 10. For example, the imaging unit 34 is moved in conjunction with the pressing member 30, and images the back surface 11b side of that region of the workpiece 11 which is pressed by the pressing member 30. Then, in reference to the image of the workpiece 11 obtained by the imaging unit 34, it is checked whether or not the workpiece 11 has been suitably divided.

As has been described above, the resin member 10 according to the present embodiment has urethane linkages deriving from the reaction between the polyether polyol and the aliphatic isocyanate. This makes it possible to exert an external force on the workpiece 11 in a state in which the workpiece 11 is supported by the resin member 10 which is less likely to undergo discoloration (yellowing). As a result, the image of the workpiece 11 obtained by the imaging unit 34 is less likely to become unclear even when the resin member 10 is used for a long period of time, so that replacement frequency of the resin member 10 is largely reduced.

Note that the structures, methods, and the like according to the present embodiment can be modified as required in carrying out the present invention, insofar as the modifications do not depart from the scope of the object of the invention.

### EXAMPLE

Next, the results of evaluation of the resin member according to the present invention will be described. In the present evaluation, variation with lapse of time of the transmittance of the resin member having urethane linkages deriving from the reaction between the polyether polyol and the aliphatic isocyanate for visible light was measured.

First, a resin member A according to Comparative Example and a resin member B according to Example were prepared. As the resin member A, a commercial product (diameter 220 mm; thickness 15 mm; Shore A hardness 70) of a disk-shaped urethane sheet formed by a polyaddition reaction between a polyol and an aromatic isocyanate was used. As the resin member B, a disk-shaped resin member (diameter 220 mm; thickness 15 mm) formed of a polyurethane produced by a polyaddition reaction between a polyol and an aliphatic isocyanate was used. As the aliphatic isocyanate, a hexamethylene diisocyanate mixture (NCO: 15% to 30%) was used. In addition, as the polyol, polypropylene glycol (trifunctional; molecular weight 3, 000) was used. Further, for synthesis of the resin member B, a crosslinking agent (dipropylene glycol) and two kinds of catalysts (catalyst A: DABCO (registered trademark) 33-LV; catalyst B: Stanoct) were used.

Note that, in the present evaluation, five kinds of the resin members B having the Shore A hardness of 50 to 90 were formed by adjusting the blending of the aliphatic isocyanate, the polyol, the crosslinking agent, and the catalysts. As a result, it was confirmed that the hardness of the resin member B can be adjusted according to the blending ratios. The blending ratios of the resin members B were as set forth in Table 1.

TABLE 1

| | Shore A hardness | | | | |
|---|---|---|---|---|---|
| | 90 | 80 | 70 | 60 | 50 |
| | Blending amount [wt %] | | | | |
| Aliphatic | 32.69 | 43.27 | 50.97 | 56.84 | 61.45 |
| isocyanate | | | | | |
| Polyol | 60.19 | 45.09 | 34.10 | 25.73 | 19.15 |
| Crosslinking | 6.69 | 11.27 | 14.61 | 17.15 | 19.15 |
| agent | | | | | |
| Catalyst A | 0.33 | 0.28 | 0.24 | 0.21 | 0.19 |
| Catalyst B | 0.10 | 0.09 | 0.08 | 0.07 | 0.06 |

The resin member A and the resin member B (Shore A hardness 70) were each stored in a room (under light of a fluorescent lamp) at room temperature (25±5° C.). In addition, at each of time points of the start of the storage, half year after the start of the storage, and one year after the start of the storage, discoloration of each of the resin members A and B was checked by visual inspection, and the transmittance of each of the resin members A and B was measured. A tintometer was used for the transmittance measurement, and the transmittance of each of the resin members A and B for visible light of a wavelength of 550 nm was measured.

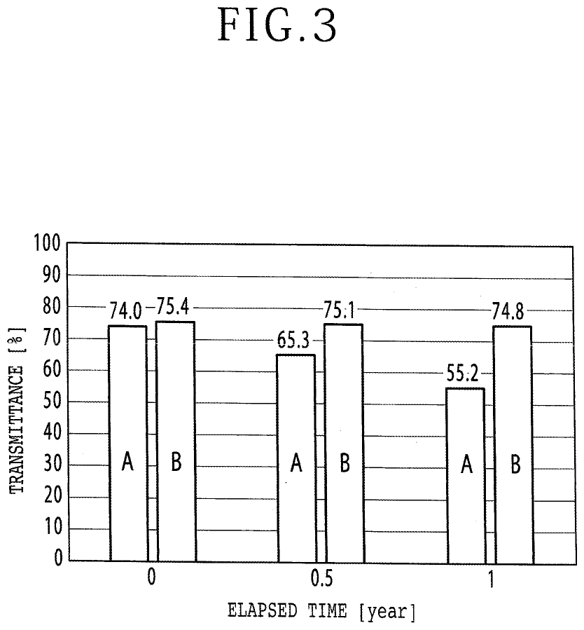

FIG. 3 is a graph depicting the transmittance of each of the resin members A and B. As the resin member A was checked by visual inspection, it was found that the resin member A was transparent at the time of start of the storage, but was gradually discolored with the lapse of time, and was yellowed to such an extent of being visually clearly confirmed one year after the start of the storage. In addition, the transmittance of the resin member A was 74.0% at the time of start of the storage, but was lowered to 65.3% half year after the start of the storage, and was further lowered down to 55.2% one year after the start of the storage.

Meanwhile, as the resin member B was checked by visual inspection, it was found that the resin member B did not show conspicuous yellowing and was maintained in a transparent state, even after the lapse of one year from the start of storage. In addition, the transmittance of the resin member B which was 75.48 at the time of start of the storage was 75.1% half year after the start of the storage, and was maintained at 74.8% even one year after the start of the storage, and, thus, the transmittance of the resin member B was little lowered even after the storage for a long period of time.

From the above-described results, it was confirmed that the resin member B according to the present invention (present Example) is less likely to be lowered in transmittance as compared to the resin member A according to Comparative Example, and is suitable as the support member (see FIG. 2) for supporting the workpiece to be imaged by the imaging unit.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A resin member for supporting a workpiece,
wherein the resin member has urethane linkages deriving from a reaction between a polyether polyol and an aliphatic isocyanate.

2. The resin member according to claim 1,
wherein the resin member has transmittance of not less than 74.8% for light of a wavelength of 550 nm.

3. The resin member according to claim 2,
wherein the resin member has Shore A hardness of 50 to 90.

4. The resin member according to claim 3, wherein the aliphatic isocyanate is hexamethylene diisocyanate.

5. A dividing apparatus that divides a workpiece formed with division start points along streets, along the streets, the dividing apparatus comprising:
a resin member that supports the workpiece;
a pressing member that presses the workpiece supported by the resin member; and
an imaging unit that images the workpiece through the resin member,
wherein the resin member has urethane linkages deriving from a reaction between a polyether polyol and an aliphatic isocyanate.

6. The dividing apparatus according to claim 5,
wherein the resin member has transmittance of not less than 74.8% for light of a wavelength of 550 nm.

7. The dividing apparatus according to claim 6, wherein the resin member has Shore A hardness of 50 to 90.

8. The dividing apparatus according to claim 7, wherein the aliphatic isocyanate is hexamethylene diisocyanate.
